(19) United States
(12) Patent Application Publication
(10) Pub. No.: US 2025/0061930 A1
(43) Pub. Date: Feb. 20, 2025

(54) Truncated Resolution for Time Sliced Computation of Multiplication and Accumulation using a Memory Cell Array

(71) Applicant: Micron Technology, Inc., Boise, ID (US)

(72) Inventor: Hernan Castro, Shingle Springs, CA (US)

(21) Appl. No.: 18/751,094

(22) Filed: Jun. 21, 2024

Related U.S. Application Data
(60) Provisional application No. 63/519,529, filed on Aug. 14, 2023.

(51) Int. Cl. G11C 7/16; G11C 7/10; G11C 7/12; G11C 8/08

(52) U.S. Cl. CPC G11C 7/16; G11C 7/1009; G11C 7/12; G11C 8/08

(57) ABSTRACT

A memory sub-system configured to perform multiplication and accumulation operations using truncated outputs. For example, voltages can be applied, according to a bit slice having a slice weight in an input, to memory cells storing weights. A resolution control can be applied, according to the slice weight, to an analog to digital converter coupled to the line having a current resulting from the memory cells responsive to the voltages. The analog to digital converter can measure at least one first bit of a quantity representative of a magnitude of the current in the line to provide a truncated output, skipping measuring of at least one second bit of the quantity according to the resolution control. Summing truncated outputs resulting from the bit slices from the input can provide an approximated result of the sum of elements in the input weighted by the weights.

### RELATED APPLICATIONS

The present application claims priority to Prov. U.S. Pat. App. Ser. No. 63/519,529 filed Aug. 14, 2023, the entire disclosures of which application are hereby incorporated herein by reference.

### TECHNICAL FIELD

At least some embodiments disclosed herein relate to computations of multiplication and accumulation in general and more particularly, but not limited to, computations of multiplication and accumulation implemented in a memory array.

### BACKGROUND

Many techniques have been developed to accelerate the computations of multiplication and accumulation. For example, multiple sets of logic circuits can be configured in arrays to perform multiplications and accumulations in parallel to accelerate multiplication and accumulation operations. For example, a memory sub-system can use a memristor crossbar or array to accelerate multiplication and accumulation operations in the electrical domain.

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The embodiments are illustrated by way of example and not limitation in the figures of the accompanying drawings in which like references indicate similar elements.

FIG. 1 shows a technique of time sliced computation with truncated resolution for multiplication and accumulation operations according to one embodiment.

FIG. 2 illustrates the truncation of a slice of the result of multiplication and accumulation operations according to one embodiment.

FIG. 3 shows the computation of a column of weight bits multiplied by a column of input bits to provide an accumulation result according to one embodiment.

FIG. 4 shows the computation of a column of multi-bit weights multiplied by a column of input bits to provide an accumulation result according to one embodiment.

FIG. 5 shows the computation of a column of multi-bit weights multiplied by a column of multi-bit inputs to provide an accumulation result according to one embodiment.

FIG. 6 shows an example computing system having a memory sub-system configured to perform multiplication and accumulation operations according to one embodiment.

FIG. 7 shows a method to perform operations of multiplication and accumulation according to one embodiment.

### DETAILED DESCRIPTION

Multiplication and accumulation operations of applying weights to inputs can be implemented via programming memory cells in an array to have states representative of weights. When voltages representative of inputs are applied to wordlines of the array, the programmed memory cells can output currents representative of the results of the inputs multiplied by the respective weights. Bitlines of the array can collect and sum the output currents. Analog to digital converters can be used to measure the magnitudes of currents in the bitlines and generate digital outputs representative of the results of the multiplication and accumulation operations.

The sum of the products between a list of weights and a respective list of inputs can be configured as the sum of the results from time-sliced computations. Each result from the time-sliced computation can provide a partial sum of the products between a list of weights and a respective list of inputs. Adding the partial sums can provide the sum of the products between the list of weights and the respective list of inputs.

For example, the bits of the inputs can be divided into slices according to bit significance. Each slice can include one or more bits of predetermined significant levels from the inputs. Instead of applying an input to a weight, a slice of significant bits from the input can be applied as an input slice to the weight. The bit slices can be applied one at a time to memory cells storing the weights to generate as partial sums, each corresponding to the sum of the products between the list of weights and a respective bit slice shifted according to the significance of the slice. The sum of the products between the list of weights and the respective list of inputs can be obtained from adding, using a digital circuit, the partial sums.

For example, an input pattern can be presented as a digital bit-stream to a memory array storing weights in a serial-parallel manner, where one bit from each input is applied at a time sequentially, and bits from multiple inputs are applied to the memory array in parallel. At each such time slice, the same significant bit level of each input pattern is presented. Also, at each such slice, the multiplication and accumulation operation as applied the weights is carried out to generate a partial sum of products. After all slices have been presented, all partial sums have been computed, which can then be combined by taking into account the significance of each slice to generate the overall sum of products.

Each time-sliced computation can be configured to be completed with a constant slice duration; and the analog to digital converters can be configured with a constant conversion resolution in generating their digital outputs for the slices.

For example, an eight-bit input vector can be applied as eight time slices, each configured to have a duration sufficient to support the multiplication with the weights, analog to digital conversion, etc.

At least some embodiments disclosed herein are configured to reduce the time used in performing the time-sliced computations. The conversion resolutions of different time slices can be reduced according to the significance of the time slices to generate truncated partial sums.

For example, the resolutions of slices can be chosen to capture the high significance partial sums with high resolution while capturing the low significance partial sums at lower resolutions.

The reduced or truncated resolutions in analog to digital conversion allows the shortening of the respective slice periods. Further, the array settling time allocated for low significance slices can be shorter than for high significance slices. Thus, reducing resolutions for low significant partial sums can shorten not only the time required to perform analog to digital conversion, but also the time for the currents in the array to settle for accurate measurements.

When results from the time slices are combined after digitization, the carry components from the slices can be ignored. The overall effect is the generation of a combination of truncated partial sum of products.

The magnitude of the error resulting from the resolution reduction for at least some of the time slices can be insignificant, relative to other sources of errors, in applications such as the computations of artificial neural networks. The benefit of the approximation can be significant in the total compute time, the energy expended in performing the computation, and/or in the area and complexity of the circuits configured to implement the computations, while still achieving the desired level of accuracy.

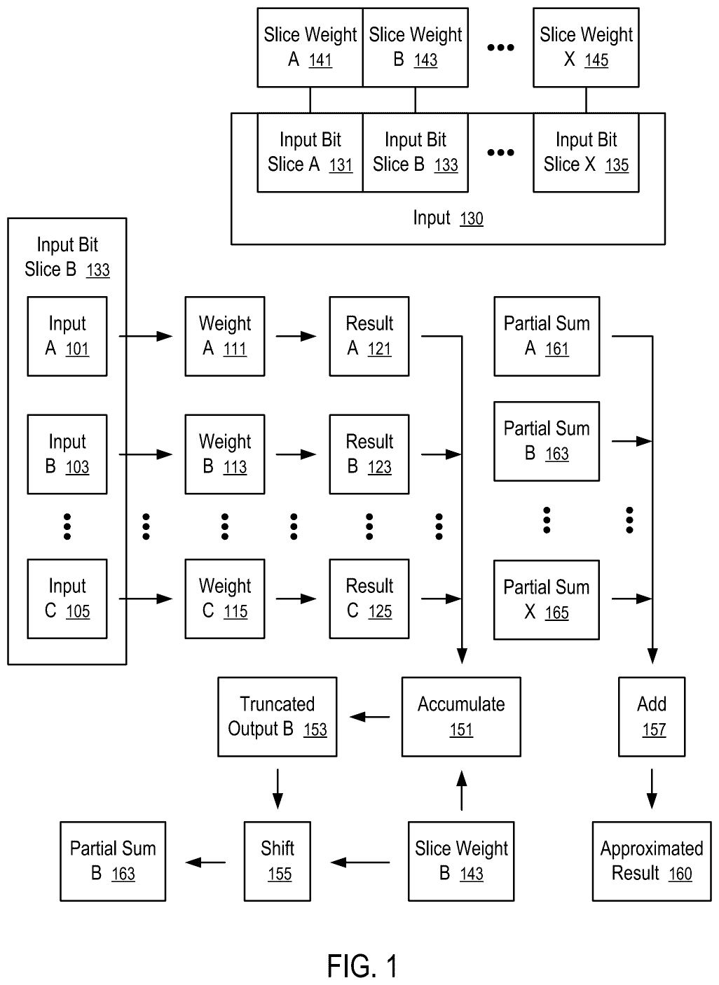

FIG. 1 shows a technique of time sliced computation with truncated resolution for multiplication and accumulation operations according to one embodiment.

In FIG. 1, a list of weights 111, 113, . . . , 115 can be used to weight a respective list of elements of an input 130; and the weighted elements of the input 130 can be summed to provide a result of multiplication and accumulation operations as applied to the weights 111, 113, . . . , 115 and the respective elements in the input 130. The result of the multiplication and accumulation operations is equal to the sum of the elements in the input 130 weighted according to the respective weights 111, 113, . . . , 115.

In a time sliced computation, the significant bits of input elements are divided into bit slices 131, 133, . . . , 135. Each bit slice has a list of a bit segment of same significance from each of the elements in the input 103.

For example, the input bit slice 133 has a list of inputs 101, 103, . . . , 105. The input 101 is a bit segment from a corresponding element of the input 130 to be weighted by the weight 111; the input 103 is a bit segment of the same significance from a corresponding element of the input 103 to be weighted by the weight 113; and the input 105 is a bit segment of the same significance from a corresponding element of the input to be weighted by the weight 115.

The input bit slices 131, 133, . . . , 135 have corresponding slice weights 141, 143, . . . , 145 according to the significance levels of the slices 131, 133, . . . , 135 in the input 130. The slice weights 141, 143, . . . , 145 correspond to the number of bitwise shifts that can be applied to move the respective bit slices (e.g., 131, 133, . . . ) to the significance level of the least significant input bit slice 135.

The input bit slices 131, 133, . . . , 135 can be applied to the weights 111, 113, . . . , 115 one slice at a time, in a same way as the application of the least significant input bit slice 135. Each of the input bit slices 131, 133, . . . , 135 has a resolution (or a count of significant bits) smaller than the input 130.

The time sliced computation allows the input 130 to be applied at a reduced resolution of slices 131, 133, . . . , 135, one slice at a time, to obtain partial sums 161, 163, . . . , 165 over a period of time. Subsequently, the partial sums 161, 163, . . . , 165 can be combined in a summation to generate the sum of the elements of the input 130 weighted by the respective weights 111, 113, . . . , 115.

When an input slice 133 is applied to the weights 111, 113, . . . , 115, the inputs 101, 103, . . . , 105 are multiplied respectively by the weights 111, 113, . . . , 115 to generate multiplication results 121, 123, . . . , 125.

In some implementations, the weights 111, 113, . . . , 115 are implemented using a column of memory cells programmed to have states representative of the weights 111, 113, . . . , 115; the inputs 101, 103, . . . , 105 are applied as voltages driven onto wordlines connected to the memory cells; and the multiplication results 121, 123, . . . , 125 are represented by currents passing through the memory cells and collected in a bitline for the operation to accumulate. An analog to digital converter can be connected to the bitline to measure the magnitude of the bitline current that corresponds to the sum of the multiplication results 121, 123, . . . , 125.

The resolution of the operation to accumulate 151 the multiplication results 121, 123, . . . , 125 and generate a digital result (e.g., via an analog to digital converter) can be controlled by the slice weight 143 of the input bit slice 133. When the resolution is reduced according to the input bit weight 143, the digital result produced by the analog to digital converter represents a truncated output 153 having a reduced number of significant bits. Reducing the resolution can reduce the time duration allocated for the generation the output 153. For example, reducing the resolution can allow a reduced time period for the bitline current to settle or become stabilized for measuring by an analog to digital converter, and allow the analog to digital converter to complete measuring in a shorter time period.

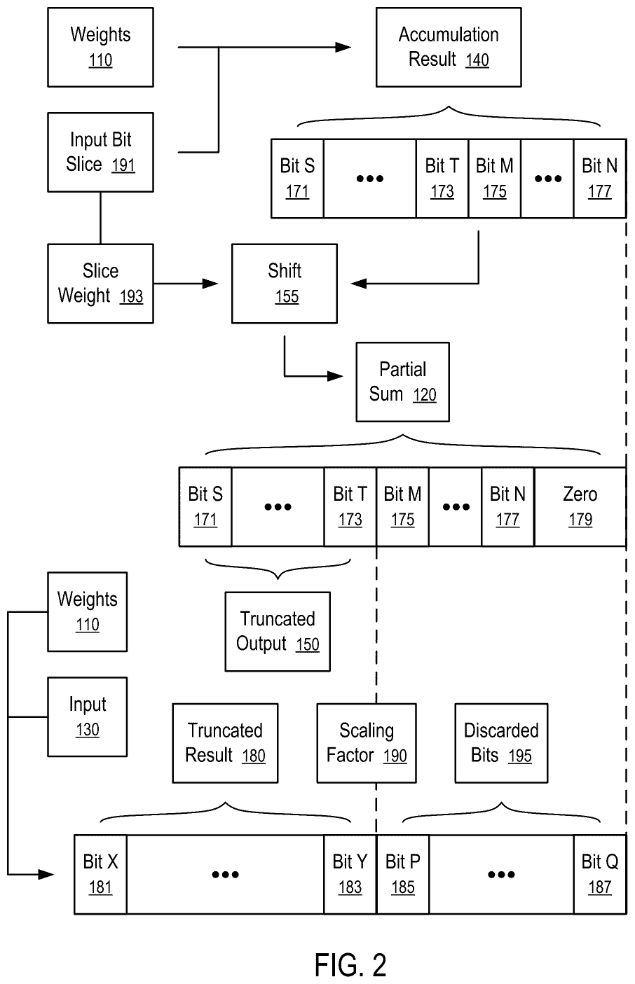

For example, when an input bit slice (e.g., 133) of a more significance level is applied, the truncated output 153 can have less bits being truncated to reduce the loss of accuracy; and when an input bit slice of a less significance level is applied, the truncated output can have more bits being truncated to reduce the time duration of the computation without significant loss of accuracy. An example of resolution truncation is illustrated in FIG. 2 and discussed further below. For example, the bits being discarded from the sum of the multiplication results 121, 123, . . . , 125 can be the corresponding least significant bits to be ignored in the result of the sum of the elements in the input 130 weighted by the respective weights 111, 113, . . . , 115.

An operation to shift 155 can be applied to the truncated output 153 according to the slice weight 143 to generate a partial sum 163 corresponding to the sum of the input bit slice 133 being weighted by the weights 111, 113, . . . , 115. The operation of shift 155 replaces the discarded bits in the truncated output 153 without bits having the value of zero.

An operation to add 157 the partial sums 161, 163, . . . , 165 resulting from the input bit slices 131, 133, . . . , 135 respectively can provide an approximated result 160 of the sum of the elements in the input 130 weighted respectively by the weights 111, 113, . . . , 115. When a predetermined number of least significant bits in the approximated results 160 is to be ignored (or discarded to retain the remaining most significant bits), the truncated output 153 can be configured to discard the bits that corresponding to the same predetermined number of least significant bits in the partial sum 163. Thus, the significant bits of truncated outputs (e.g., 153) are aligned via truncation according to the slice weights (e.g., 143) and thus ready for summation without the operation to shift 155. The truncated outputs (e.g., 153) resulting from the input bit slices 131, 133, . . . , 135 can be summed at a reduced resolution without applying the operation to shift 155, which arrangement can reduce the size and/or complexity of the circuits used to compute the sum of the partial sums 161, 163, . . . , 165.

Since the partial sums 161, 163, . . . , 165 are computed with truncation, the approximated result 160 computed from the operation to add 157 the partial sums 161, 163, . . . , 165 can be different from the accurate sum of the elements of the input 130 weighted by the respective weights 111, 113, . . . , 115. The difference (and thus the approximation error in the approximated result 160) is typically a small fraction of the accurate sum of the elements in the input 130 weighted respectively by the weights 111, 113, . . . , 115. The different (and thus the approximation error) can be insignificant in many applications, such as in the computations of artificial neural networks.

FIG. 2 illustrates the truncation of a slice of the result of multiplication and accumulation operations according to one embodiment.

In FIG. 2, the sum of the elements of the input 130 weighted by the respective weights 110 is configured to be truncated to retain bits 181, . . . , 183 as a truncated result 180 by discarding a predetermined number of least significant bits 185, . . . , 187. Thus, the approximated result 160 of the sum can be represented using the bits 181, . . . , 183 of the truncated result 180 without the discarded bits 195. The approximated result 160 is equal to left shifting the truncated result 180 according to a scaling factor 190 to fill the discarded bits 195 with zeros. The scaling factor 190 corresponds to the predetermined number of least significant bits 185, . . . , 187 being discarded.

As in FIG. 1, the sum of the elements of the input 130 weighted by the respective weights 110 can be computed from partial sums (e.g., 161, 163, . . . , 165) obtained by applying the weights 110 to input bit slices (e.g., 131, 133, . . . , 135).

For example, a typical input bit slice 191 having a slice weight 193 (corresponding to the significant level of the input bit slice 191 in the input 130) can be applied to the weights 110 to generate an accumulation result 140.

The sum of the elements in the input bit slice 191 (e.g., 133 in FIG. 1) weighted according to the respective weights 110 (e.g., 111, 113, . . . , 115 in FIG. 1) provides an accumulation result 140. A full resolution accumulation result 140 (e.g., as the accurate sum of the multiplication results 121, 123, . . . , 125) has bits 171, . . . , 173, 175, . . . , 177, including the most significant bit 171 and the least significant bit 177.

The operation to shift 155 according to the slice weight 193 of the input bit slice 191 can be applied to the accumulation result 140 to generate a partial sum 120 having bits 171, . . . , 173, 175, . . . , 177 followed by a number of bits having the value of zero 179.

In FIG. 2, the same predetermined number of least significant bits being discarded from the sum of the elements of the input 130 weighted by the respective weights 110 are also discarded from the partial sum 120. Thus, bits 175, . . . , 177 from the accumulation result 140 can be discarded to obtain a truncated output 150 resulting from the input bit slice 191 without applying the operation to shift 155. The count of bits 175, . . . , 177 to be discarded from the accumulation result corresponds to the difference between the predetermined number of discarded bits 195 and the number of bitwise shift 155 to be applied according to the slice weight 193.

The truncated outputs (e.g., 150) resulting from the input bit slices (e.g., 191) of the input 130 can be summed to compute the truncated result 180 without the discarded bits 195.

In general, the sum of the truncated outputs (e.g., 150) for the input bit slices (e.g., 191) of the input 130 can be different from the truncated result 180 from the sum of the elements of the input 130 weighted by the respective weights 110. In some instances, the sum of the discarded bits of the partial sums (e.g., 120, such as bits 175, . . . , 177) can produce a carry component that is to be carried into one or more least significant bits (e.g., 183) of the truncated result 180. By discarding the bits (e.g., 175, . . . , 177) from the partial sum 120, the carry component is also discarded. As a result, there can be an error of losing the carry component by truncating the bits (e.g., 175, . . . , 177) before summing the partial sums (e.g., 120) of the input bit slices (e.g., 191).

The maximum magnitude of the carry component corresponds to bits (e.g., 175, . . . , 177) being discarded from the partial sums (e.g., 120) each having the value of one. The carry component is typically small when compared to the magnitude of the truncated result 180. Thus, the operation to accumulate 151 can be configured to measure the bits 171, . . . , 173 of the truncated output 150 without measuring the discarded bits (e.g., 175, . . . , 177) of the partial sum 120.

There are advantages in using the truncated outputs (e.g., 150).

For example, skipping the measuring of the bits 175, . . . , 177 can allow the use of a shortened period for the settling of the bitline current when the application of the weights 110 are implemented via memory cells in an array.

Further, skipping the measuring of the bits 175, . . . , 177 can reduce the time used by an analog to digital converter in producing the truncated output 150.

Further, reducing the resolution in computing the truncated result 180 by skipping the operations on the predetermined number of least significant bits (e.g., corresponding to the discarded bits 195) can reduce the size and complexity of the circuits configured to add the partial sums (e.g., 120). Since the discarded bits (e.g., 175, . . . , 177) are not being operated upon, the circuits can be configured to skip the operation to shift 155 and sum the truncated outputs (e.g., 150) to obtain an approximation that corresponds to the truncated result 180 minus the carry component.

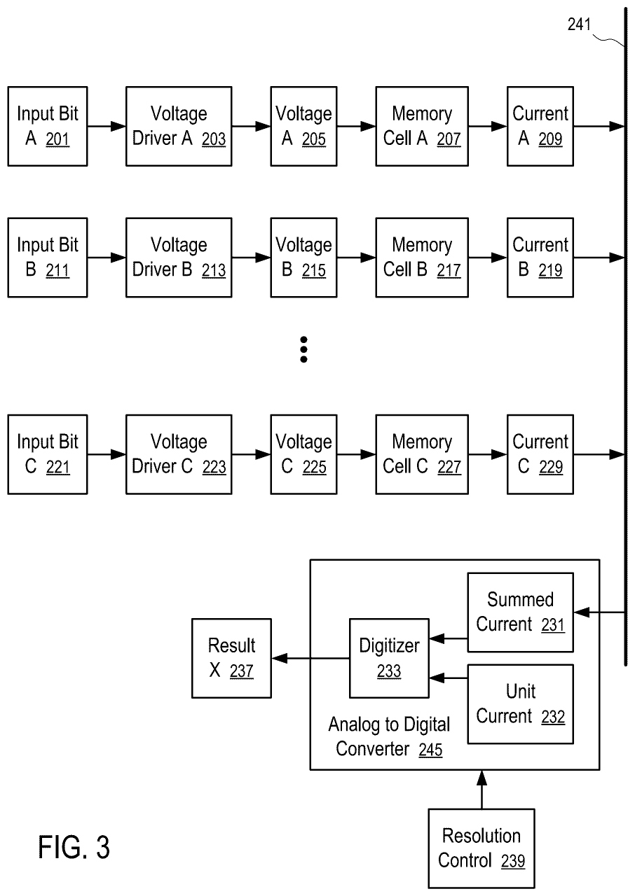

FIG. 3 shows the computation of a column of weight bits multiplied by a column of input bits to provide an accumulation result according to one embodiment. For example, bits of weights 111, 113, . . . , 115 in FIG. 1. can be configured in a way as illustrated in FIG. 3 to perform multiplication and accumulation operations applied to the input 130 and the weights 111, 113, . . . , 115.

In FIG. 3, a column of synapse memory cells 207, 217, . . . , 227 (e.g., in the memory cell array of an analog computing module) can be programmed in the synapse mode to have threshold voltages at levels representative of weights stored one bit per memory cell.

The column of memory cells 207, 217, . . . , 227, programmed in the synapse mode, can be read in a synapse mode, during which voltage drivers 203, 213, . . . , 223 are configured to apply voltages 205, 215, . . . , 225 concurrently to the memory cells 207, 217, . . . , 227 respectively according to their received input bits 201, 211, . . . , 221.

For example, when the input bit 201 has a value of one, the voltage driver 203 applies the predetermined read voltage as the voltage 205, causing the memory cell 207 to output the predetermined amount of current as its output current 209 if the memory cell 207 has a threshold voltage programmed at a lower level, which is lower than the predetermined read voltage, to represent a stored weight of one, or to output a negligible amount of current as its output current 209 if the memory cell 207 has a threshold voltage programmed at a higher level, which is higher than the predetermined read voltage, to represent a stored weight of zero. However, when the input bit 201 has a value of zero, the voltage driver 203 applies a voltage (e.g., zero) lower than the lower level of threshold voltage as the voltage 205 (e.g., does not apply the predetermined read voltage), causing the memory cell 207 to output a negligible amount of current at its output current 209 regardless of the weight stored in the memory cell 207. Thus, the output current 209 as a multiple of the predetermined amount of current is representative of the result of the weight bit, stored in the memory cell 207, multiplied by the input bit 201.

Similarly, the current 219 going through the memory cell 217 as a multiple of the predetermined amount of current is representative of the result of the weight bit, stored in the memory cell 217, multiplied by the input bit 211; and the current 229 going through the memory cell 227 as a multiple of the predetermined amount of current is representative of the result of the weight bit, stored in the memory cell 227, multiplied by the input bit 221.

The output currents 209, 219, . . . , and 229 of the memory cells 207, 217, . . . , 227 are connected to a common line 241 (e.g., bitline) for summation. The summed current 231 is compared to the unit current 232, which is equal to the predetermined amount of current, by a digitizer 233 of an analog to digital converter 245 to determine the digital result 237 of the column of weight bits, stored in the memory cells 207, 217, . . . , 227 respectively, multiplied by the column of input bits 201, 211, . . . , 221 respectively with the summation of the results of multiplications.

The sum of negligible amounts of currents from memory cells connected to the line 241 is small when compared to the unit current 232 (e.g., the predetermined amount of current). Thus, the presence of the negligible amounts of currents from memory cells does not alter the result 237 and is negligible in the operation of the analog to digital converter 245.

In FIG. 3, the voltages 205, 215, . . . , 225 applied to the memory cells 207, 217, . . . , 227 are representative of digitized input bits 201, 211, . . . , 221; the memory cells 207, 217, . . . , 227 are programmed to store digitized weight bits; and the currents 209, 219, . . . , 229 are representative of digitized results. Thus, the memory cells 207, 217, . . . , 227 do not function as memristors that convert analog voltages to analog currents based on their linear resistances over a voltage range; and the operating principle of the memory cells in computing the multiplication is fundamentally different from the operating principle of a memristor crossbar. When a memristor crossbar is used, conventional digital to analog converters are used to generate an input voltage proportional to inputs to be applied to the rows of memristor crossbar. When the technique of FIG. 3 is used, such digital to analog converters can be eliminated; and the operation of the digitizer 233 to generate the result 237 can be greatly simplified. The result 237 is an integer that is no larger than the count of memory cells 207, 217, . . . , 227 connected to the line 241. The digitized form of the output currents 209, 219, . . . , 229 can increase the accuracy and reliability of the computation implemented using the memory cells 207, 217, . . . , 227.

In FIG. 3, the analog digital converter 245 has an input configured to receive resolution control 239. The resolution control 239 can be used to control the truncation of bits in a digital representation of the magnitude of the current in the line 241.

For example, the resolution control 239 can be generated according to slice weight 143 of the bit slice represented by the input bits 201, 211, . . . , 221.

For example, when the resolution control 239 is applied according to the slice weight 193 in FIG. 2, the measurement of the accumulation result 140 represented by the magnitude of the current in the line 241 can be configured to skip the measuring of bits 175, . . . , 177 and generate the truncated output 150 as the result 237.

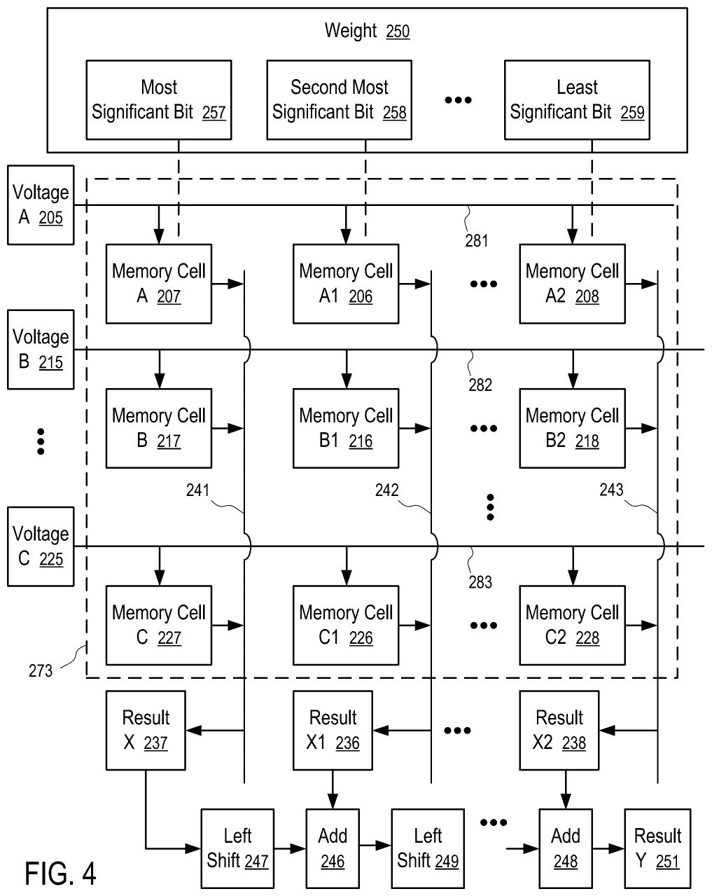

In general, a weight involving a multiplication and accumulation operation can be more than one bit. Multiple columns of memory cells can be used to store the different significant bits of weights, as illustrated in FIG. 4 to perform multiplication and accumulation operations.

The circuit illustrated in FIG. 3 can be considered a multiplier-accumulator unit configured to operate on a column of 1-bit weights and a column of 1-bit inputs. Multiple such circuits can be connected in parallel to implement a multiplier-accumulator unit to operate on a column of multi-bit weights and a column of 1-bit inputs, as illustrated in FIG. 4.

The circuit illustrated in FIG. 3 can also be used to read the data stored in the memory cells 207, 217, . . . , 227. For example, to read the data or weight stored in the memory cell 207, the input bits 211, . . . , 221 can be set to zero to cause the memory cells 217, . . . , 227 to output negligible amount of currents into the line 241 (e.g., as a bitline). The input bit 201 is set to one to cause the voltage driver 203 to apply the predetermined read voltage. Thus, the result 237 from the digitizer 233 provides the data or weight stored in the memory cell 207. Similarly, the data or weight stored in the memory cell 217 can be read via applying one as the input bit 211 and zeros as the remaining input bits in the column; and data or weight stored in the memory cell 227 can be read via applying one as the input bit 221 and zeros as the other input bits in the column.

In general, the circuit illustrated in FIG. 3 can be used to select any of the memory cells 207, 217, . . . , 227 for read or write. A voltage driver (e.g., 203) can apply a programming voltage pulse to adjust the threshold voltage of a respective memory cell (e.g., 207) to erase data, to store data or weigh, etc.

FIG. 4 shows the computation of a column of multi-bit weights multiplied by a column of input bits to provide an accumulation result according to one embodiment.

For example, a weight 111 (or 113, or 115) in FIG. 1 can be implemented using a row of memory cells 207, 206, . . . , 207, in a way as implementing the weight 250 having bits 257, 258, . . . , 259.

In FIG. 4, a weight 250 in a binary form has a most significant bit 257, a second most significant bit 258, . . . , a least significant bit 259. The significant bits 257, 258, . . . , 259 can be stored in rows of memory cells 207, 206, . . . , 208 (e.g., in the memory cell array of an analog computing module) across a number of columns respectively in an array 273. The significant bits 257, 258, 259 of the weight 250 are to be multiplied by the input bit 201 represented by the voltage 205 applied on a line 281 (e.g., a wordline) by a voltage driver 203 (e.g., as in FIG. 3).

Similarly, memory cells 217, 216, . . . , 218 can be used to store the corresponding significant bits of a next weight (e.g., 113) to be multiplied by a next input bit 211 represented by the voltage 215 applied on a line 282 (e.g., a wordline) by a voltage driver 213 (e.g., as in FIG. 3); and memory cells 227, 226, . . . , 228 can be used to store corresponding of a weight (e.g., 115) to be multiplied by the input bit 221 represented by the voltage 225 applied on a line 283 (e.g., a wordline) by a voltage driver 223 (e.g., as in FIG. 3).

The most significant bits (e.g., 257) of the weights (e.g., 250) stored in the respective rows of memory cells in the array 273 are multiplied by the input bits 201, 211, . . . , 221 represented by the voltages 205, 215, . . . , 225 and then summed as the current 231 in a line 241 and digitized using a digitizer 233, as in FIG. 3, to generate a result 237 corresponding to the most significant bits of the weights.

Similarly, the second most significant bits (e.g., 258) of the weights (e.g., 250) stored in the respective rows of memory cells in the array 273 are multiplied by the input bits 201, 211, . . . , 221 represented by the voltages 205, 215,., 225 and then summed as a current in a line 242 and digitized to generate a result 236 corresponding to the second most significant bits.

Similarly, the least most significant bits (e.g., 259) of the weights (e.g., 250) stored in the respective rows of memory cells in the array 273 are multiplied by the input bits 201, 211, . . . , 221 represented by the voltages 205, 215, . . . , 225 and then summed as a current in a line 243 and digitized to generate a result 238 corresponding to the least significant bit.

The most significant bit can be left shifted by one bit to have the same weight as the second significant bit, which can be further left shifted by one bit to have the same weight as the next significant bit. Thus, the result 237 generated from multiplication and summation of the most significant bits (e.g., 257) of the weights (e.g., 250) can be applied an operation of left shift 247 by one bit; and the operation of add 246 can be applied to the result of the operation of left shift 247 and the result 236 generated from multiplication and summation of the second most significant bits (e.g., 258) of the weights (e.g., 250). The operations of left shift (e.g., 247, 249) can be used to apply weights of the bits (e.g., 257, 258, . . . ) for summation using the operations of add (e.g., 246, . . . , 248) to generate a result 251. Thus, the result 251 is equal to the column of weights in the array 273 of memory cells multiplied by the column of input bits 201, 211, . . . , 221 with multiplication results accumulated.

In some implementations, a memory cell can be programmed to output a multiple of the unit current 232 when the predetermined voltage is applied, and output a negligible amount of current when the applied voltage is smaller than the predetermined voltage. Thus, the memory cell (e.g., 207) can be programmed to represent the value of a bit of the weight (e.g., 250) and its weight over another memory cell (e.g., 206).

For example, when the most significant bit 257 has a value of one, the memory cell 207 is programmed to have a state such that when the predetermined voltage representative of an input bit 201 having a value of one is applied to the memory cell 207, the memory cell 207 outputs 2 times the unit current, such that the current magnitude of the bitline 241 has a bit weight built in the currents generated by the memory cells 207, 217, . . . , 227. As a result the currents in the bitline 241 and 242 can be connected to a common line for measuring using a same analog to digital converter 245. Such an arrangement can reduce the number of analog to digital converters 245 configured to generate digitized results (e.g., truncated outputs 153).

In some implementations, a memory cell (e.g., 207) can be programmed to generate 4 times the unit current when applied the predetermined voltage representative of an input bit 201 having a values of one; and another memory cell (e.g., 206) can be programmed to generate 2 times the unit current when applied the predetermined voltage representative of the input bit 201 having the values of one. Thus, the memory cells 207 and 206 can be programmed to store the most significant bit 257 and the second most significant but 258 with bit weights relative to a further memory cell programmed to store the third most significant bit. Since the currents in the bitlines 241, 242 connected to the memory cells 207 and 206 have built-in bit weights relative to the bitline connected to the further memory cells, the three bitlines can be connected to a common line for accumulation and for measuring using a same analog to digital converter 245. Thus, the number of analog to digital converters 245 configured to generate digitized results (e.g., truncated outputs 153) can be further reduced. Further, the circuits configured to perform the operations of left shift (e.g., 247) and add (e.g., 246) can be reduced.

In some implementations, a memory cell (e.g., 207) can be programmed to output an amount of current that is a multiple of the unit current 232 corresponding to the value of a bit segment (e.g., 257 and 258) of a weight (e.g., 250). Thus, the memory cell (e.g., 207) can be programmed to store the bit segment and thus reduce the number of memory cells configured to store the weight (e.g., 250).

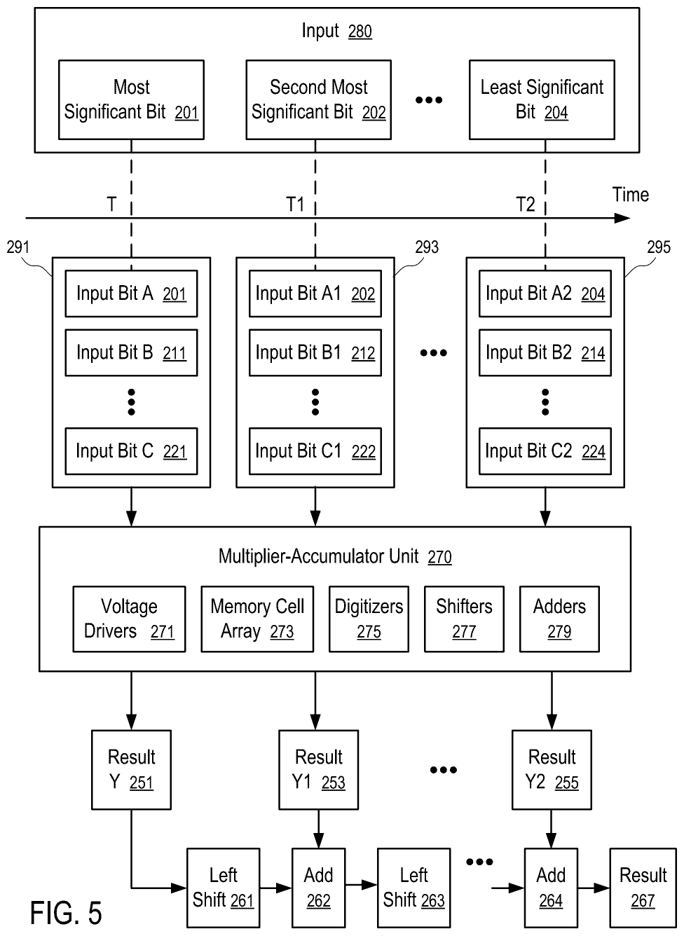

In general, an input involving a multiplication and accumulation operation can be more than one bit. Columns of input bits can be applied one column at a time to the weights stored in the array 273 of memory cells to obtain the result of a column of weights multiplied by a column of inputs with results accumulated as illustrated in FIG. 5.

The circuit illustrated in FIG. 4 can be used to read the data stored in the array 273 of memory cells. For example, to read the data or weight 250 stored in the memory cells 207, 206, . . . , 208, the input bits 211, . . . , 221 can be set to zero to cause the memory cells 217, 216, . . . , 218, . . . , 227, 226, . . . , 228 to output negligible amount of currents into the line 241, 242, . . . , 243 (e.g., as bitlines). The input bit 201 is set to one to cause the voltage driver 203 to apply the predetermined read voltage as the voltage 205. Thus, the results 237, 236, . . . , 238 from the digitizers (e.g., 233) connected to the lines 241, 242, . . . , 243 provide the bits 257, 258, . . . , 259 of the data or weight 250 stored in the row of memory cells 207, 206, . . . , 208. Further, the result 251 computed from the operations of shift 247, 249, . . . and operations of add 246, . . . , 248 provides the weight 250 in a binary form.

In general, the circuit illustrated in FIG. 4 can be used to select any row of the memory cell array 273 for read. Optionally, different columns of the memory cell array 273 can be driven by different voltage drivers. Thus, the memory cells (e.g., 207, 206, . . . , 208) in a row can be programmed to write data in parallel (e.g., to store the bits 257, 258, . . . , 259) of the weight 250.

FIG. 5 shows the computation of a column of multi-bit weights multiplied by a column of multi-bit inputs to provide an accumulation result according to one embodiment.

In FIG. 5, the significant bits of inputs (e.g., 280) are applied to a multiplier-accumulator unit 270 at a plurality of time instances T, T1, . . . , T2.

For example, a multi-bit input 280 can have a most significant bit 201, a second most significant bit 202, . . . , a least significant bit 204.

At time T, an input bit slice 291 having the most significant bits 201, 211, . . . , 221 of the inputs (e.g., 280) can be applied to the multiplier-accumulator unit 270 to obtain a result 251 of weights (e.g., 250), stored in the memory cell array 273, multiplied by the column of bits 201, 211, . . . , 221 with summation of the multiplication results.

The result 251 can be a truncated output controlled using a resolution control 239 applied based on the slice weight of the most significant bits 201, 211, . . . , 221.

For example, the multiplier-accumulator unit 270 can be implemented in a way as illustrated in FIG. 4. The multiplier-accumulator unit 270 has voltage drivers 271 connected to apply voltages 205, 215, . . . , 225 representative of the input bits 201, 211, . . . , 221. The multiplier-accumulator unit 270 has a memory cell array 273 storing bits of weights as in FIG. 4. The multiplier-accumulator unit 270 has digitizers 275 to convert currents summed on lines 241, 242, . . . , 243 for columns of memory cells in the array 273 to output results 237, 236, . . . , 238. The multiplier-accumulator unit 270 has shifters 277 and adders 279 connected to combine the column result 237, 236, . . . , 238 to provide a result 251 as in FIG. 4. In some implementations, the logic circuits of the multiplier-accumulator unit 270 (e.g., shifters 277 and adders 279) are implemented as part of the inference logic circuit of an analog computing module.

Similarly, at time T1, an input bit slice 293 having the second most significant bits 202, 212, . . . , 222 of the inputs (e.g., 280) can be applied to the multiplier-accumulator unit 270 to obtain a result 253 of weights (e.g., 250) stored in the memory cell array 273 and multiplied by the vector of bits 202, 212, . . . , 222 with summation of the multiplication results.

Similarly, at time T2, an input bit slice 295 having the least significant bits 204, 214, . . . , 224 of the inputs (e.g., 280) can be applied to the multiplier-accumulator unit 270 to obtain a result 255 of weights (e.g., 250), stored in the memory cell array 273, multiplied by the vector of bits 202, 212, . . . , 222 with summation of the multiplication results.

For example, the input bit slices 131, 133, . . . , 135 in FIG. 1 can be implemented via bit slices 291, 293, . . . , 295 of FIG. 5.

The result 251 generated from multiplication and summation of the most significant bits 201, 211, . . . , 221 of the inputs (e.g., 280) can be applied an operation of left shift 261 by one bit; and the operation of add 262 can be applied to the result of the operation of left shift 261 and the result 253 generated from multiplication and summation of the second most significant bits 202, 212, . . . , 222 of the inputs (e.g., 280). The operations of left shift (e.g., 261, 263) can be used to apply weights of the bits (e.g., 201, 202, . . . ) for summation using the operations of add (e.g., 262, . . . , 264) to generate a result 267. Thus, the result 267 is equal to the weights (e.g., 250) in the array 273 of memory cells multiplied by the column of inputs (e.g., 280) respectively and then summed.

Alternatively, the results 251, 253, . . . , 255 can be configured as truncated outputs (e.g., 153) to have a same level of a weight corresponding to the scaling factor 190 for the truncated result 180. Thus, the circuits to perform the left shift 261, 263 can be eliminated; and the results 251, 253, . . . , 255 can be summed to obtain the result 267 that corresponds to the truncated result 180 in FIG. 2.

In some implementations, a current accumulator (e.g., a capacitor) is configured on a bitline (e.g., 241) to generate a parameter that is the integration of the bitline current over a time period. The time period can be configured according to a bit weight of a significant bit (e.g., 201). An analog to digital converter can be configured to measure the parameter generated using the current accumulator.

Optionally, the current generated in a bitline (e.g., 241) for successive bit slices (e.g., 291 and 293) can be accumulated in the current accumulator for measuring in one operation. Thus, the successive bit slices (e.g., 291 and 293) can be combined and viewed as one bit slice.

A plurality of multiplier-accumulator unit 270 can be connected in parallel to operate on a matrix of weights multiplied by a column of multi-bit inputs over a series of time instances T, T1, . . . , T2.

Optionally, the memory cells (e.g., 207, . . . , 227) can be implemented using memristors each having a substantial constant resistance value in a range of applied voltages. Thus, the resistance values of the memristors can be programmed to represent the weights 111, 113, . . . , 115. An input slice (e.g., 191) having one or more significant bits from each element of the input 130 can be applied as voltages having magnitudes corresponding to the inputs in the slice (e.g., 191). The current through the memristors in the bitline can be measured using an analog to digital converter 245 with a resolution control 239 to generate a truncated output 153. Thus, an input slice (e.g., 191) can have one or more bits of a same significance level from each element of the input 130.

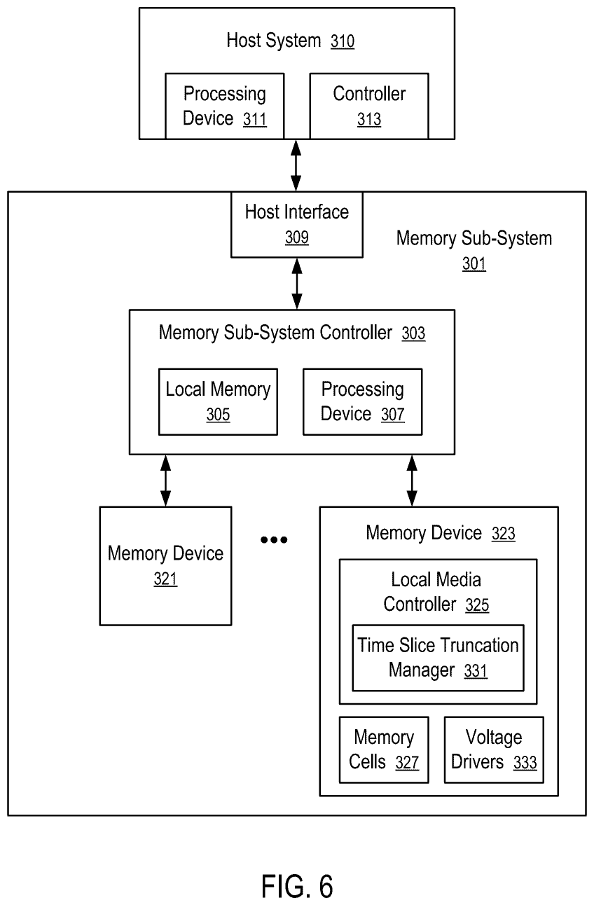

FIG. 6 shows an example computing system having a memory sub-system configured to perform multiplication and accumulation operations according to one embodiment.

The example computing system of FIG. 6 includes a host system 310 and a memory sub-system 301. An analog compute module (e.g., having the memory cells 207, 217, . . . , 227 and an analog to digital converter 245 controlled via a resolution control 239 as in FIG. 3) can be configured in the memory sub-system 301, or in the host system 310.

The memory sub-system 301 can include media, such as one or more volatile memory devices (e.g., memory device 321), one or more non-volatile memory devices (e.g., memory device 323), or a combination of such.

For example, the memory device 323 can include memory cells 327 configured to store weights 111, 113, . . . , 115 (e.g., as memory cells in the array 273 in FIG. 4). The memory device 323 can include voltage drivers 333 configured to apply input bit slices as the voltage drivers 203, 213, . . . , 223 in FIG. 3, or voltage drivers 271 as in FIG. 5. The memory device 323 can include analog to digital converters (e.g., 245) with resolution control 239. A local media controller 325 of the memory device 323 can include a time slice truncation manager 331 configured to adjust the resolution control 239 of the analog to digital converters (e.g., 245) according to the slice weight (e.g., 141, 143, . . . , or 145) of the input bit slice (e.g., 131, 133, . . . , or 135) being applied via the voltage drivers 333 to the memory cells 327.

A memory sub-system 301 can be a storage device, a memory module, or a hybrid of a storage device and memory module. Examples of a storage device include a solid-state drive (SSD), a flash drive, a universal serial bus (USB) flash drive, an embedded multi-media controller (eMMC) drive, a universal flash storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The computing system can be a computing device such as a desktop computer, a laptop computer, a network server, a mobile device, a vehicle (e.g., airplane, drone, train, automobile, or other conveyance), an internet of things (IoT) enabled device, an embedded computer (e.g., one included in a vehicle, industrial equipment, or a networked commercial device), or such a computing device that includes memory and a processing device.

The computing system can include a host system 310 that is coupled to one or more memory sub-systems 301. FIG. 6 illustrates one example of a host system 310 coupled to one memory sub-system 301. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 310 can include a processor chipset (e.g., processing device 311) and a software stack executed by the processor chipset. The processor chipset can include one or more cores, one or more caches, a memory controller (e.g., controller 313) (e.g., NVDIMM controller), and a storage protocol controller (e.g., PCIe controller, SATA controller). The host system 310 uses the memory sub-system 301, for example, to write data to the memory sub-system 301 and read data from the memory sub-system 301.

The host system 310 can be coupled to the memory sub-system 301 via a physical host interface 309. Examples of a physical host interface 309 include, but are not limited to, a serial advanced technology attachment (SATA) interface, a peripheral component interconnect express (PCIe) interface, a universal serial bus (USB) interface, a fibre channel, a serial attached SCSI (SAS) interface, a double data rate (DDR) memory bus interface, a small computer system interface (SCSI), a dual in-line memory module (DIMM) interface (e.g., DIMM socket interface that supports double data rate (DDR)), an open NAND flash interface (ONFI), a double data rate (DDR) interface, a low power double data rate (LPDDR) interface, or any other interface. The physical host interface 309 can be used to transmit data between the host system 310 and the memory sub-system 301. The host system 310 can further utilize an NVM express (NVMe) interface to access components (e.g., memory devices 323) when the memory sub-system 301 is coupled with the host system 310 by the PCIe interface. The physical host interface 309 can provide an interface for passing control, address, data, and other signals between the memory sub-system 301 and the host system 310. FIG. 6 illustrates a memory sub-system 301 as an example. In general, the host system 310 can access multiple memory sub-systems via a same communication connection, multiple separate communication connections, and/or a combination of communication connections.

The processing device 311 of the host system 310 can be, for example, a microprocessor, a central processing unit (CPU), a processing core of a processor, an execution unit, etc. In some instances, the controller 313 can be referred to as a memory controller, a memory management unit, and/or an initiator. In one example, the controller 313 controls the communications over a bus coupled between the host system 310 and the memory sub-system 301. In general, the controller 313 can send commands or requests to the memory sub-system 301 for desired access to memory devices 323, 321. The controller 313 can further include interface circuitry to communicate with the memory sub-system 301. The interface circuitry can convert responses received from the memory sub-system 301 into information for the host system 310.

The controller 313 of the host system 310 can communicate with the controller 303 of the memory sub-system 301 to perform operations such as reading data, writing data, or erasing data at the memory devices 323, 321 and other such operations. In some instances, the controller 313 is integrated within the same package of the processing device 311. In other instances, the controller 313 is separate from the package of the processing device 311. The controller 313 and/or the processing device 311 can include hardware such as one or more integrated circuits (ICs) and/or discrete components, a buffer memory, a cache memory, or a combination thereof. The controller 313 and/or the processing device 311 can be a microcontroller, special purpose logic circuitry (e.g., a field programmable gate array (FPGA), an application specific integrated circuit (ASIC), etc.), or another suitable processor.

The memory devices 323, 321 can include any combination of the different types of non-volatile memory components and/or volatile memory components. The volatile memory devices (e.g., memory device 321) can be, but are not limited to, random access memory (RAM), such as dynamic random access memory (DRAM) and synchronous dynamic random access memory (SDRAM).

Some examples of non-volatile memory components include a negative-and (or, NOT AND) (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 323 can include one or more arrays of memory cells 327. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 323 can include one or more arrays of memory cells such as SLCs, MLCs, TLCs, QLCs, PLCs, or any combination of such. In some embodiments, a particular memory device can include an SLC portion, an MLC portion, a TLC portion, a QLC portion, and/or a PLC portion of memory cells. The memory cells of the memory devices 323 can be grouped as pages that can refer to a logical unit of the memory device used to store data. With some types of memory (e.g., NAND), pages can be grouped to form blocks.

Although non-volatile memory devices such as 3D cross-point type and NAND type memory (e.g., 2D NAND, 3D NAND) are described, the memory device 323 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), spin transfer torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller 303 (or controller 303 for simplicity) can communicate with the memory devices 323 to perform operations such as reading data, writing data, or erasing data at the memory devices 323 and other such operations (e.g., in response to commands scheduled on a command bus by controller 313). The controller 303 can include hardware such as one or more integrated circuits (ICs) and/or discrete components, a buffer memory, or a combination thereof. The hardware can include digital circuitry with dedicated (i.e., hard-coded) logic to perform the operations described herein. The controller 303 can be a microcontroller, special purpose logic circuitry (e.g., a field programmable gate array (FPGA), an application specific integrated circuit (ASIC), etc.), or another suitable processor.

The controller 303 can include a processing device 307 (processor) configured to execute instructions stored in a local memory 305. In the illustrated example, the local memory 305 of the controller 303 includes an embedded memory configured to store instructions for performing various processes, operations, logic flows, and routines that control operation of the memory sub-system 301, including handling communications between the memory sub-system 301 and the host system 310.

In some embodiments, the local memory 305 can include memory registers storing memory pointers, fetched data, etc. The local memory 305 can also include read-only memory (ROM) for storing micro-code. While the example memory sub-system 301 in FIG. 6 has been illustrated as including the controller 303, in another embodiment of the present disclosure, a memory sub-system 301 does not include a controller 303, and can instead rely upon external control (e.g., provided by an external host, or by a processor or controller separate from the memory sub-system).

In general, the controller 303 can receive commands or operations from the host system 310 and can convert the commands or operations into instructions or appropriate commands to achieve the desired access to the memory devices 323. The controller 303 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 323. The controller 303 can further include host interface circuitry to communicate with the host system 310 via the physical host interface. The host interface circuitry can convert the commands received from the host system into command instructions to access the memory devices 323 as well as convert responses associated with the memory devices 323 into information for the host system 310.

The memory sub-system 301 can also include additional circuitry or components that are not illustrated. In some embodiments, the memory sub-system 301 can include a cache or buffer (e.g., DRAM) and address circuitry (e.g., a row decoder and a column decoder) that can receive an address from the controller 303 and decode the address to access the memory devices 323.

In some embodiments, the memory devices 323 include local media controllers 325 that operate in conjunction with the memory sub-system controller 303 to execute operations on one or more memory cells of the memory devices 323. An external controller (e.g., memory sub-system controller 303) can externally manage the memory device 323 (e.g., perform media management operations on the memory device 323). In some embodiments, a memory device 323 is a managed memory device, which is a raw memory device combined with a local controller (e.g., local media controller 325) for media management within the same memory device package. An example of a managed memory device is a managed NAND (MNAND) device.

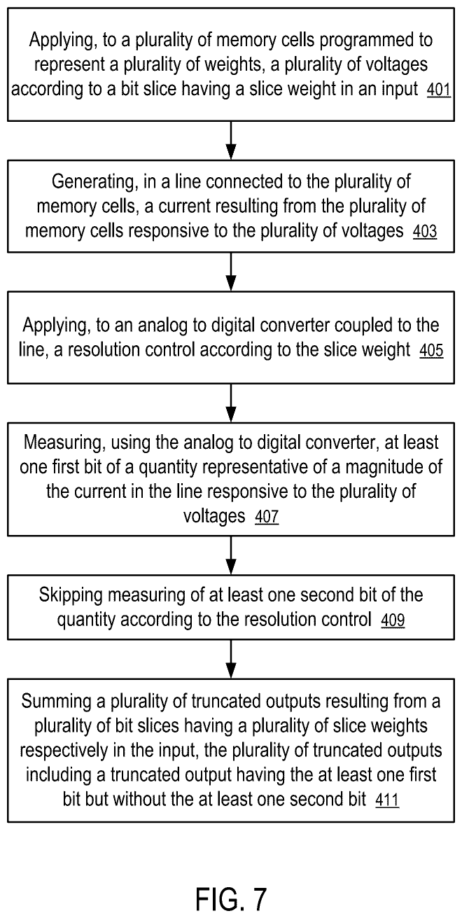

FIG. 7 shows a method to perform operations of multiplication and accumulation according to one embodiment. For example, the method can be implemented in a computing system or device of FIG. 6.

At block 401, the method includes applying, to a plurality of memory cells (e.g., 207, 217, . . . , 227) programmed to represent a plurality of weights (e.g., one or more bits of weights 111, 113, . . . , 115), a plurality of voltages (e.g., 203, 213, . . . , 223) according to a bit slice (e.g., 191 or 133) having a slice weight (e.g., 193 or 143) in an input (e.g., 130). For example, in a computing system or device (e.g., as in FIG. 6), the memory cells (e.g., 207, 217, . . . , 227) are connected to a plurality of wordlines (e.g., 281, 282, . . . , 283) to receive the plurality of voltages (e.g., 203, 213, . . . , 223). Responsive to the applied voltages (e.g., 203, 213, . . . , 223), the memory cells (e.g., 207, 217, . . . , 227) allow amounts of currents to pass through into a bitline (e.g., 241) connected to the memory cells (e.g., 207, 217, . . . , 227). The amount of current passing through each of the memory cells (e.g., 207, 217, . . . , 227) is representative of the multiplication result (e.g., 121, 123, . . . , 125) generated from a respective input (e.g., 101, 103, . . . , 105) in the bit slice (e.g., 133) and a respective weight (e.g., 111, 113, . . . , 115).

For example, a logic circuit (e.g., a controller 325 or 303, or a processing device 307) of the computing system or device can be configured (e.g., via instructions, firmware, and/or software) to perform the method of FIG. 7, including the function of the time slice truncation manager 331.

For example, the computing system or device can have voltage drivers 271 (e.g., 203, 213, . . . , 223) operable to apply voltages according to instructions or control signals from the logic circuit. The logic circuit can use the voltage drivers to apply programming voltages to program the states of the memory cells (e.g., 207, 217, . . . , 227) to represent weights (e.g., 111, 113, . . . , 115) to apply input voltages (e.g., 205, 215, . . . , 225) representative of input bits (e.g., 201, 211, . . . , 221) or inputs (e.g., 101, 103, . . . , 105) of an input bit slice (e.g., 133) to cause the memory cells (e.g., 207, 217, 227) to output currents into the bitline (e.g., 241) corresponding to multiplication results (e.g., 121, 123, . . . , 125).

For example, the input 130 has a plurality of elements to be weighted by the plurality of weights (e.g., 111, 113, . . . , 115) respectively; and the bit slice (e.g., 133) includes one bit (e.g., input 101, 103, . . . , or 105; or input bit 201, 211, . . . , or 221) of a same significance level from each of the plurality of elements.

For example, each of the plurality of weights (e.g., 111, 113, . . . , 115) can be a one-bit value stored in a respective memory cell (e.g., 207, 217, . . . , or 227). Alternatively, more than one memory cell connected to a same bitline (e.g., 241) can be combined to store a weight (e.g., 111, 113, . . . , 115) having a multi-bit value. Alternatively, a memory cell can be programmed to store a weight having a multi-bit value.

In some implementations, the memory cells (e.g., 207, 217, . . . , 227) are memristors programmed to have conductance representative of the weights (e.g., 111, 113, . . . , 115).

In some implementations, the memory cells (e.g., 207, 217, . . . , 227) have nonlinear current voltage curves; and each of the memory cells (e.g., 207, 217, . . . , 227) can be programmed to output currents at a level representative a weight stored in the memory cell in response to a predetermined voltage, representative of an input bit (e.g., 201, 211, . . . , or 221) having a value of one, being applied to the memory cell.

At block 403, the method includes generating, in a line (e.g., bitline 241) connected to the plurality of memory cells (e.g., 207, 217, . . . , 227), a current resulting from the plurality of memory cells (e.g., 207, 217, . . . , 227) responsive to the plurality of voltages (e.g., 203, 213, . . . , 223).

For example, the current in the bitline 241 is the sum of the currents passing through the memory cells 205, 215, . . . , 225 into the bitline 241.

At block 405, the method includes applying, to an analog to digital converter 245 coupled to the line (e.g., bitline 241), a resolution control (e.g., 239) according to the slice weight (e.g., 193 or 143).

At block 407, the method includes measuring, using the analog to digital converter 245, at least one first bit (e.g., 171, . . . , 173) of a quantity representative of a magnitude of the current in the line (e.g., bitline 241) responsive to the plurality of voltages (e.g., 203, 213, . . . , 223).

At block 409, the method includes skipping measuring of at least one second bit (e.g., 175, . . . , 177) of the quantity according to the resolution control (e.g., 239).

At block 411, the method includes summing a plurality of truncated outputs (e.g., 153, 150) resulting from a plurality of bit slices (e.g., 131, 133, . . . , 135) having a plurality of slice weights (e.g., 141, 143, . . . , 145) respectively in the input 130. The plurality of truncated outputs includes a truncated output (e.g., 153 or 150) having the at least one first bit (e.g., 171, . . . , 173) but without the at least one second bit (e.g., 175, . . . , 177).

Optionally, the method can further include: controlling, based on the resolution control 239 or the slice weight (e.g., 193 or 143), a length of a time period allocated to allow the current to settle in the line (e.g., bitline 241) before the measuring of the at least one first bit (e.g., 171, . . . , 173).

For example, the plurality of truncated outputs (e.g., 153 or 150) from the analog to digital converter 245 are summed without a shifting operation (e.g., corresponding to left shift 261) to align significant bits of the plurality of truncated outputs (e.g., 153 or 150).

For example, the plurality of truncated outputs (e.g., 153 or 150) are truncated by the analog to digital converter 245 according to the resolution control 239 to have a same level of weight (e.g., the same weight as the scaling factor 190 for the truncated result 180).

For example, the method can further include: providing, based on summing the plurality of truncated outputs (e.g., 153 or 150), an approximated result 160 of truncating a sum of the plurality of elements weighted by the plurality of weights (e.g., 111, 113, . . . , 115) respectively.

For example, the approximated result 160 can include a truncated result 180 and a scaling factor 190 to discard a predetermined number of least significant bits (e.g., 185, . . . , 187); each of the plurality of truncated outputs (e.g., 150) corresponds to a partial sum (e.g., 120) being truncated to discard the same predetermined number of least significant bits (e.g., 175, . . . , 177, and zero 179); and the partial sum (e.g., 120) is equal to shifting, according to a respective slice weight (e.g., 193), a sum of a respective bit slice (e.g., 191), among the plurality of bit slices (e.g., 131, 133, . . . , 135), having the respective slice weight (e.g., 193) and weighted according to the plurality of weights (e.g., 111, 113, . . . , 115).

In one embodiment, an example machine of a computer system within which a set of instructions, for causing the machine to perform any one or more of the methods discussed herein, can be executed. In some embodiments, the computer system can correspond to a host system that includes, is coupled to, or utilizes a memory sub-system or can be used to perform the operations described above. In alternative embodiments, the machine can be connected (e.g., networked) to other machines in a LAN, an intranet, an extranet, or the internet, or any combination thereof. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a personal digital assistant (PDA), a cellular telephone, a web appliance, a server, a network router, a switch or bridge, a network-attached storage facility, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system includes a processing device, a main memory (e.g., read-only memory (ROM), flash memory, dynamic random access memory (DRAM) such as synchronous DRAM (SDRAM) or Rambus DRAM (RDRAM), static random access memory (SRAM), etc.), and a data storage system, which communicate with each other via a bus (which can include multiple buses).

Processing device represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device can also be one or more special-purpose processing devices such as an application specific integrated circuit (ASIC), a field programmable gate array (FPGA), a digital signal processor (DSP), network processor, or the like. The processing device is configured to execute instructions for performing the operations and steps discussed herein. The computer system can further include a network interface device to communicate over the network.

The data storage system can include a machine-readable medium (also known as a computer-readable medium) on which is stored one or more sets of instructions or software embodying any one or more of the methodologies or functions described herein. The instructions can also reside, completely or at least partially, within the main memory and within the processing device during execution thereof by the computer system, the main memory and the processing device also constituting machine-readable storage media. The machine-readable medium, data storage system, or main memory can correspond to the memory sub-system.

In one embodiment, the instructions include instructions to implement functionality corresponding to the operations described above. While the machine-readable medium is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to convey the substance of their work most effectively to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In this description, various functions and operations are described as being performed by or caused by computer instructions to simplify description. However, those skilled in the art will recognize what is meant by such expressions is that the functions result from execution of the computer instructions by one or more controllers or processors, such as a microprocessor. Alternatively, or in combination, the functions and operations can be implemented using special-purpose circuitry, with or without software instructions, such as using application-specific integrated circuit (ASIC) or field-programmable gate array (FPGA). Embodiments can be implemented using hardwired circuitry without software instructions, or in combination with software instructions. Thus, the techniques are limited neither to any specific combination of hardware circuitry and software, nor to any particular source for the instructions executed by the data processing system.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method, comprising:
applying, to a plurality of memory cells programmed to represent a plurality of weights, a plurality of voltages according to a bit slice having a slice weight in an input;
generating, in a line connected to the plurality of memory cells, a current resulting from the plurality of memory cells responsive to the plurality of voltages;
applying, to an analog to digital converter coupled to the line, a resolution control according to the slice weight;
measuring, using the analog to digital converter, at least one first bit of a quantity representative of a magnitude of the current in the line responsive to the plurality of voltages; and
summing a plurality of truncated outputs resulting from a plurality of bit slices having a plurality of slice weights respectively in the input, the plurality of truncated outputs including a truncated output having the at least one first bit.

2. The method of claim 1, further comprising:
controlling, based on the resolution control, a length of a time period allocated to allow the current to settle in the line before the measuring of the at least one first bit;
wherein measuring of at least one second bit of the quantity is skipped according to the resolution control; and
wherein the plurality of truncated outputs exclude the at least one second bit.

3. The method of claim 2, wherein the input has a plurality of elements to be weighted by the plurality of weights respectively; and the bit slice includes one bit of a same significance level from each of the plurality of elements.

4. The method of claim 3, wherein the plurality of truncated outputs from the analog to digital converter are summed without a shifting operation to align significant bits of the plurality of truncated outputs.

5. The method of claim 3, wherein the plurality of truncated outputs are truncated to have a same level of weight.

6. The method of claim 5, further comprising:
providing, based on summing the plurality of truncated outputs, an approximated result of truncating a sum of the plurality of elements weighted by the plurality of weights respectively.

7. The method of claim 6, wherein each of the plurality of weights has a one-bit value.

8. The method of claim 6, wherein the approximated result has a scaling factor to discard a predetermined number of least significant bits; each of the plurality of truncated outputs corresponds to a partial sum being truncated to discard the same predetermined number of least significant bits; and the partial sum is equal to shifting, according to a respective slice weight, a sum of a respective bit slice, among the plurality of bit slices, having the respective slice weight and weighted according to the plurality of weights.

9. A device, comprising:
a plurality of memory cells programmable to represent a plurality of weights;
a plurality of wordlines connected to the plurality of memory cells;
a bitline connected to collect currents going through the plurality of memory cells;
voltage drivers operable to apply, to the plurality of memory cells via the plurality of wordlines, a plurality of voltages according to a bit slice having a slice weight in an input;
an analog to digital converter coupled to the bitline and configured with a resolution control; and
a logic circuit configured to apply the resolution control according to the slice weight in measurement of, using the analog to digital converter, at least one first bit of a quantity representative of a magnitude of a current in the bitline responsive to the plurality of voltages being applied to the plurality of memory cells; and
wherein the logic circuit is configured to sum a plurality of truncated outputs resulting from a plurality of bit slices having a plurality of slice weights respectively in the input, the plurality of truncated outputs including a truncated output having the at least one first bit but.

10. The device of claim 9, wherein the logic circuit is configured to control a length of a time period allocated to allow the current to settle in the bitline before onset of the measurement;
wherein the analog to digital converter is configured to skip measuring of at least one second bit of the quantity according to the resolution control; and
wherein the truncated output excludes the at least one second bit.

11. The device of claim 10, wherein the input has a plurality of elements to be weighted by the plurality of weights respectively; and the bit slice includes one bit of a same significance level from each of the plurality of elements.

12. The device of claim 11, wherein the plurality of truncated outputs are truncated to have a same level of weight.

13. The device of claim 12, wherein the logic circuit is configured to provide a sum of the plurality of truncated outputs as an approximated result of truncating a sum of the plurality of elements weighted by the plurality of weights respectively.

14. The device of claim 13, wherein the approximated result has a scaling factor to discard a predetermined number of least significant bits; each of the plurality of truncated outputs corresponds to a partial sum being truncated to discard the same predetermined number of least significant bits; and the partial sum is equal to shifting, according to a respective slice weight, a sum of a respective bit slice, among the plurality of bit slices, having the respective slice weight and weighted according to the plurality of weights.

15. The device of claim 11, wherein the plurality of truncated outputs from the analog to digital converter are summed without a shifting operation being applied to align significant bits of the plurality of truncated outputs.

16. A system, comprising:
a memory cell array having a plurality of memory cells connected to a plurality of wordlines and a bitline;
voltage drivers; and
at least one analog to digital converter;
a processor configured to:
program the plurality of memory cells to store a plurality of weights;
identify a bit slice having a slice weight in an input;
instruct the voltage drivers to apply, via the wordlines, a plurality of voltages according to the bit slice; and
instruct the analog to digital converter to generate a truncated output from measurement of a current in the bitline resulting from the plurality of memory cells responsive to the plurality of voltages, wherein the analog to digital converter to measure at least one first bit of a quantity representative of a magnitude of the current in the line responsive to the plurality of voltages;
wherein the system is configured sum a plurality of truncated outputs, resulting from a plurality of bit slices having a plurality of slice weights respectively in the input, to provide an approximated result of a sum of the input having a plurality of elements weighted by the plurality of weights respectively.

17. The system of claim 16, further configured to control, based on the slice weight, a length of a time period allocated to allow the current to settle in the bitline before the measuring of the at least one first bit; and wherein the analog to digital converter is configured to skip measurement of at least one second bit of the quantity.

18. The system of claim 17, wherein the plurality of truncated outputs are truncated to have a same level of weight.

19. The system of claim 18, wherein each of the plurality of weights has a one-bit value.

20. The system of claim 19, wherein the approximated result has a scaling factor to discard a predetermined number of least significant bits; each of the plurality of truncated outputs corresponds to a partial sum being truncated to discard the same predetermined number of least significant bits; and the partial sum is equal to shifting, according to a respective slice weight, a sum of a respective bit slice, among the plurality of bit slices, having the respective slice weight and weighted according to the plurality of weights.
